(19) United States
(12) Patent Application Publication
(10) Pub. No.: US 2026/0096061 A1
(43) Pub. Date: Apr. 2, 2026

(54) METHODS AND SYSTEMS FOR HIGH POWER THERMALLY STABLE SMALL HEAT PIPES

(71) Applicant: Meta Platforms, Inc., Menlo Park, CA (US)

(72) Inventors: Michael Nikkhoo, Saratoga, CA (US); Shankhadeep Das, Union City, CA (US)

(21) Appl. No.: 19/347,450

(22) Filed: Oct. 1, 2025

Related U.S. Application Data
(60) Provisional application No. 63/701,868, filed on Oct. 1, 2024.

(51) Int. Cl. H05K 7/20; G02B 27/01

(52) U.S. Cl. CPC H05K 7/20336; G02B 27/017; G02B 2027/0178

(57) ABSTRACT

The disclosure can include a system and device for heat dissipation associated with a mixed reality device which includes a tubular member comprising a proximal end and a distal end. The tubular member comprises a shell and defines a vapor cavity and the tubular member is sealed at the proximal and distal ends. The heat dissipation device includes an outer heating engine oriented in the vapor cavity. The outer heating engine is adjacent to an inner surface wall of the tubular member. The heat dissipation device includes an inner heating engine oriented inside of the outer heating engine, wherein an outer surface of the inner heating engine defines a supplemental cavity bounded by an inner wall of the tubular member and the outer surface of the inner heating engine.

### CROSS-REFERENCE TO RELATED APPLICATIONS

This present application claims the benefit of priority under 35 U.S.C. § 119 (e) to U.S. Provisional Application No. 63/701,868, filed Oct. 1, 2024, the disclosure of which is hereby incorporated by reference in its entirety for all purposes.

### TECHNICAL FIELD

This application generally relates to a system of heat dissipation in a mixed reality device. The described system is more specifically for small scale heat dissipation in mixed reality headsets.

### BACKGROUND

A desirable aspect of mixed reality headsets comprises the ability to move autonomously without being tethered to a power source via an external power cable or charging cable during use. Thermal stability is an important factor in mixed reality device, ensuring the device functions reliably and comfortably without overheating. Issues arise when the components of the device generate heat. Overheating can lead to the user experiencing hot spots or discomfort within minutes of use. To address these issues, manufacturers employ various strategies, including efficient heat dissipation materials, optimized component placement, and advanced thermal management techniques to maintain a safe operating temperature and prevent overheating.

### SUMMARY

In an embodiment of the disclosure, a device for heat dissipation associated with a mixed reality device includes a tubular member comprising a proximal end and a distal end. The tubular member comprises a shell and defines a vapor cavity and the tubular member is sealed at the proximal and distal ends. The heat dissipation device includes an outer heating engine oriented in the vapor cavity. The outer heating engine is adjacent to an inner surface wall of the tubular member. The heat dissipation device includes an inner heating engine oriented inside of the outer heating engine, wherein an outer surface of the inner heating engine defines a supplemental cavity bounded by an inner wall of the tubular member and the outer surface of the inner heating engine. The outer heat engine comprises a plurality of wires, and the plurality of wires are grouped into bundles such that the bundles are oriented in an overlapping woven arrangement formed into an outer circular shell.

The inner heat engine comprises a plurality of wires, wherein the plurality of wires are grouped into bundles such that the bundles are oriented in an overlapping woven arrangement formed into an inner circular shell. The tubular member, the outer circular shell of the outer heating engine, and the inner circular shell of the inner heating engine can be oriented in a concentric orientation. The inner heating engine encapsulates the vapor cavity by an inner surface of the inner circular shell. The wire bundle associated with the inner heat engine comprises more wires per bundle than the wire bundle associated with the outer heat engine. A wire diameter of the plurality of wires associated with the outer heat engine are greater than a wire diameter of the plurality of wires associated with the inner heat engine. The overlapping woven arrangement formed into the inner circular shell and the outer circular shell defines at least one interstitial space comprising an area dimension. The area dimension of the at least one interstitial space associated with the outer heat engine is greater than the area dimension of the at least one interstitial space associated with the inner heat engine. The heating tube comprises a transport fluid, and the transportation fluid is encapsulated between an inner surface of the tubular member and an exterior surface of the outer heating engine. In a further aspect, the outer heating engine and inner heating engine span a length dimension between the proximal and the distal end of the tubular member. The tubular member, and wires of the outer engine and inner engine, can be composed of copper or copper alloy. In an alternate embodiment, the tubular member, and wires of the outer engine and inner engine can comprise glass. The tubular member is structured to be oriented in a temple cavity located in a temple member of a pair of glasses. The tubular member is sealed at the proximal and distal end and pressurized. In a further aspect, the tubular member comprises a diameter ranging from approximately 1.0 mm to 2.0 mm.

In another embodiment, a mixed reality device comprises a computing device configured to be encapsulated by a structural component of the mixed reality device, and includes a tubular member comprising a proximal end and a distal end. The tubular member comprises a shell and defines a vapor cavity and the tubular member is sealed at the proximal and distal ends. The heat dissipation device includes an outer heating engine oriented in the vapor cavity. The outer heating engine is adjacent to an inner surface wall of the tubular member. The heat dissipation device includes an inner heating engine oriented inside of the outer heating engine, wherein an outer surface of the inner heating engine defines a supplemental cavity bounded by an inner wall of the tubular member and the outer surface of the inner heating engine. The tubular member also includes a transport fluid encapsulated by a boundary defined by an interior surface of the tubular member and an exterior surface of the outer heating engine.

### BRIEF DESCRIPTION OF THE DRAWINGS

For a better understanding of the various described embodiments, reference should be made to the Detailed Description below, in conjunction with the following drawings.

FIG. 1 depicts a mixed reality set of glasses with a zoomed in internal view inside the temple of the glasses, according to the disclosure.

FIG. 2 depicts a lengthwise cross-sectional view of a heating pipe.

FIG. 3A depicts the outer heat engine and FIG. 3B depicts the inner heat engine.

FIG. 4A depicts the inner heat engine oriented internally to the outer heat engine.

FIG. 4B depicts a lengthwise cross-sectional view of FIG. 4A.

FIG. 4C depicts an end-wise cross-sectional view of FIG. 4A.

FIG. 5. depicts a zoom view of an interstitial space between bundles of wires.

FIG. 6 depicts a side view of a mixed reality head set glasses worn by a user

FIG. 7 depicts testing results of the temperature vs time for the implementation of a heating pipe.

FIG. 8. depicts testing results of temperature vs. power for the implementation of a heating pipe.

FIG. 9 depicts testing results of temperature variance vs. power for the implementation of a heating pipe.

In accordance with common practice, the various features illustrated in the drawings may not be drawn to scale. Accordingly, the dimensions of the various features may be arbitrarily expanded or reduced for clarity. In addition, some of the drawings may not depict all of the components of a given system, method, or device. Finally, consistent with common practice, like reference numerals may be used to denote like features throughout the specification and figures.

### DETAILED DESCRIPTION

Numerous details are described herein to provide a thorough understanding of the example embodiments illustrated in the accompanying drawings. However, some embodiments may be practiced without some of the specific details. Furthermore, well-known processes, components, and materials have not necessarily been described in exhaustive detail so as to avoid obscuring pertinent aspects of the embodiments described herein.

The disclosure addresses issues involving heat generation from computing devices in a mixed reality or augmented reality headset. For example, when the mixed reality device comprises a set of glasses, a computing device will need to be smaller in order to properly fit in the headset. With the smaller spatial confines for the computing devices in a mixed reality device, there is a need to transfer that heat away from the computing device in order to maximize computing capacity as well as prevent any potential harm to the computing device and to the user of the mixed reality device from repetitive heat cycles.

In one aspect, unless otherwise stated, all measurements, values, ratings, positions, magnitudes, sizes, and other specifications that are set forth in this specification, including in the clauses/claims that follow, are approximate, not exact. In one aspect, they are intended to have a reasonable range, such that values modified with ‘approximately’ are intended to include boundary values (e.g., +/−10%) that is consistent with the functions to which they relate and with what is customary in the art to which they pertain. It is understood that some or all steps, operations, or processes may be performed automatically, without the intervention of a user. Method clauses may be provided to present elements of the various steps, operations, or processes in a sample order, and are not meant to be limited to the specific order or hierarchy presented.

Embodiments of this disclosure may include or be implemented in conjunction with various types or embodiments of mixed reality systems. Mixed reality, as described herein, is any superimposed functionality and/or sensory-detectable presentation provided by a mixed reality system within (or rendered to appear on top of) a user's physical surroundings. Such mixed realities may include and/or represent virtual reality (VR), augmented reality (AR) or some combination and/or variation of one of these. For example, a user may perform a swiping in-air hand gesture to cause a song to be skipped by a song-providing API providing playback at, for example, a home speaker. In some embodiments of an AR system, ambient light (e.g., a live feed of the surrounding environment that a user would normally see) may be passed through a display element of a respective head-wearable device presenting aspects of the MR system. In some embodiments, ambient light may be passed through respective aspects of the AR system. For example, a visual user interface element (e.g., a notification user interface element) may be presented at the head-wearable device, and an amount of ambient light (e.g., 15-50% of the ambient light) may be passed through the user interface element, such that the user may distinguish at least a portion of the physical environment over which the user interface element is being displayed.

Embodiments of the disclosed technology may include or be implemented in conjunction with a mixed reality system. The term “mixed reality” or “MR” as used herein refers to a form of reality that has been adjusted in some manner before presentation to a user, which may include, e.g., virtual reality (VR), augmented reality (AR), extended reality (XR), hybrid reality, or some combination and/or derivatives thereof. Mixed reality content may include completely generated content or generated content combined with captured content (e.g., real-world photographs). The mixed reality content may include video, audio, haptic feedback, or some combination thereof, any of which may be presented in a single channel or in multiple channels (such as stereo video that produces a three-dimensional (3D) effect to the viewer). Additionally, in some embodiments, mixed reality may be associated with applications, products, accessories, services, or some combination thereof, that are, e.g., used to interact with content in an immersive application. The mixed reality system that provides the mixed reality content may be implemented on various platforms, including a head-mounted display (HMD) connected to a server, a host computer system, a standalone HMD, a mobile device or computing system, a “cave” environment or other projection system, or any other hardware platform capable of providing mixed reality content to one or more viewers. Mixed reality may be equivalently referred to herein as “artificial reality.”

“Virtual reality” or “VR,” as used herein, refers to an immersive experience where a user's visual input is controlled by a computing system. “Augmented reality” or “AR” as used herein refers to systems where a user views images of the real world after they have passed through a computing system. For example, a tablet with a camera on the back can capture images of the real world and then display the images on the screen on the opposite side of the tablet from the camera. The tablet can process and adjust or “augment” the images as they pass through the system, such as by adding virtual objects. AR also refers to systems where light entering a user's eye is partially generated by a computing system and partially composes light reflected off objects in the real world. For example, an AR headset could be shaped as a pair of glasses with a pass-through display, which allows light from the real world to pass through a waveguide that simultaneously emits light from a projector in the AR headset, allowing the AR headset to present virtual objects intermixed with the real objects the user can see. The AR headset may be a block-light headset with video pass-through. “Mixed reality” or “MR,” as used herein, refers to any of VR, AR, XR, or any combination or hybrid thereof.

In certain aspects, safety and privacy protocols are implemented so that the user understands user eye data is obtained by the system. The user is informed in advance of the purpose for obtaining of the eye data, and may at any time opt out of the eye data being obtained. In certain aspects, the user may delete any past eye data stored by the system. Users who proceed with using the system may be notified that respective eye-movement data is being obtained for the purpose of determining pupil location as a representation of focusing direction of the user's eyes to more efficiently generate a foveated view in that respective direction.

Mixed reality content may include completely generated content or generated content combined with captured (e.g., real-world) content. The mixed reality content may include video, audio, haptic events, or some combination thereof, any of which may be presented in a single channel or in multiple channels (such as stereo video that produces a three-dimensional effect to a viewer). Additionally, in some embodiments, mixed reality may also be associated with applications, products, accessories, services, or some combination thereof, which are used, for example, to create content in mixed reality and/or are otherwise used in (e.g., to perform activities in) mixed reality.

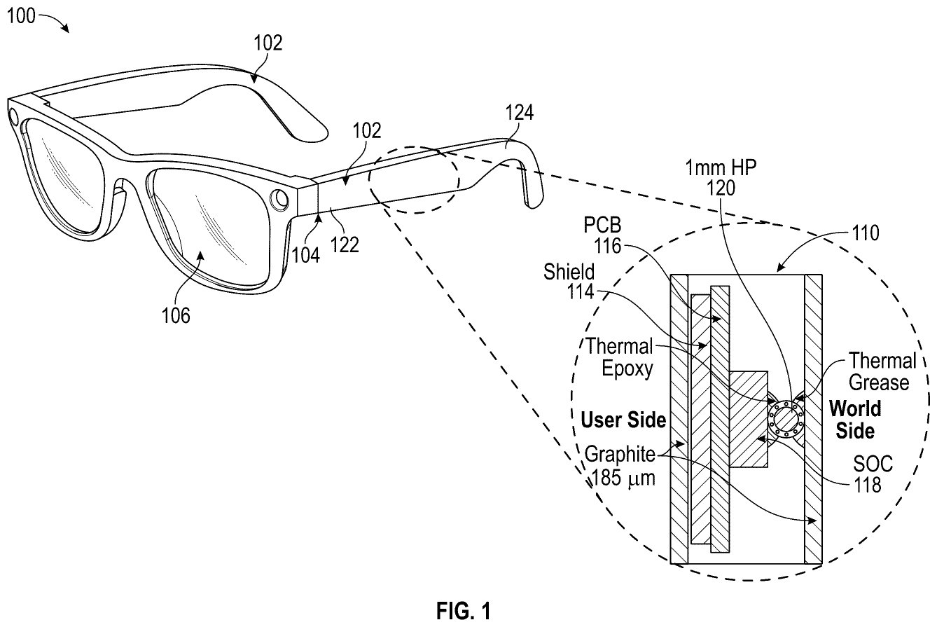

As shown in FIG. 1, an exemplary augmented reality device can comprise a pair of glasses. For the glasses, the frame of the glasses can comprise temple members 102 that extend from a proximal end 124 in proximity to the hinge 104 at the lens area 106 and extend to a distal end 124 in proximity to a temple tip engage the user's ear. Within a cavity defined by a body of the temple member 102 in proximity of the computing device of the AR device 100, is a heat dissipation system 110. The temple member 102 can comprise the heat dissipation system 110 in proximity to the computing devices. The orientation of the temple member 102 can be oriented between the world side and the user side. The user side defines the region closer to the user's temple and the world side defines the region adjacent to the ambient environment. In one embodiment, the temple member 102 can comprise a material such as graphite. In the absence of a heat dissipation mechanism, graphite as a sole material may not reasonably reduce heat generated by the computing device. In a further aspect, the first layer of protection from the user can be a heat shield 114. The heat shield 114 can function as a thermal insulator; the thermal insulator mitigates heat transfer progressing to a user's face and maintaining user comfort. In one aspect, the heat shield material can be a foam type material, wherein other materials used to dissipate and absorb heat are also considered. Adjacent to the heat shield 114 can be the computing devices, including a printed circuit board (PCB) 116 and a System on a Chip (SOC) 118. The SOC 118 can comprise a single microchip that integrates, including processors, memory, and input/output (I/O) controllers. The computing devices can comprise the primary generators of heat for the MR device. Further, the computing devices can generate a great amount of heat in a very small space (e.g., the cavity defined as the temple member). The heat generated can provide discomfort to the wearer but can also diminish the processing capacity of the computing device. Thus another aspect improved by the disclosure is the ΔT, which represents the temperature variation. As more power is applied to the system, the lower temperature variation reduces thermal stress on materials like a thermal epoxy joint. A lower ΔT as function of the heating pipe mitigates the electronic and mechanical components degrading due to thermal cycling. Further, an excessive temperature rise typically indicates more power is being lost as heat, reducing overall system efficiency. The heat dissipation system for the MR device 100 can comprise a heat pipe (HP) 120 that extends the length of the temple member 102. The heating tube can comprise a length dimension consistent with a proximal end 122 and a distal end 124 of the temple member 102, wherein the proximal end can be located adjacent to the heat source generated by the computing devices. In a further aspect, the system can comprise an epoxy or additional filler material to maintain the structural integrity of the heat pipe 120 in the cavity of temple member 102.

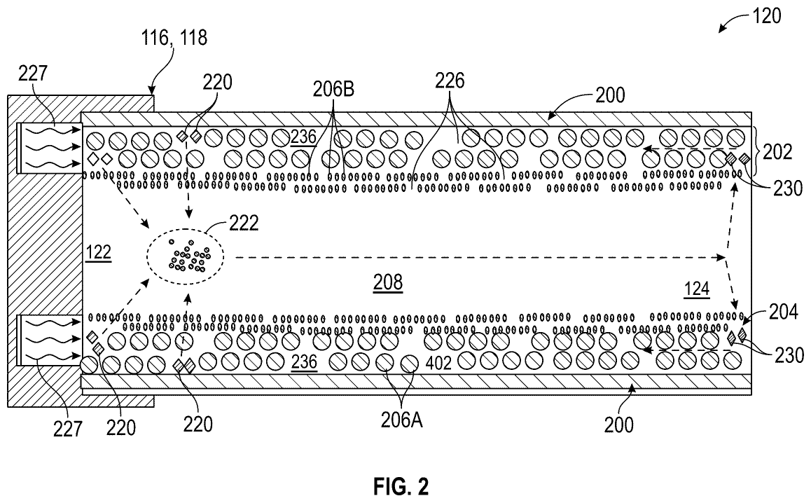

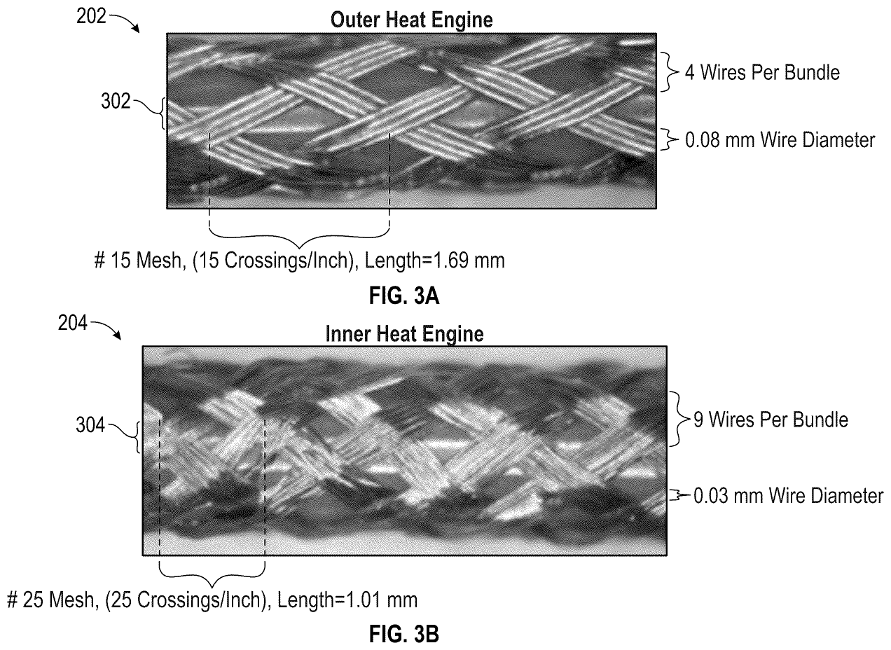

Discussed previously, the heat pipe 120 can be the conduit that transfers heat away from the computing devices of the MR device. As depicted in FIG. 2, the heat pipe 120 can comprise a tubular member 200. Within the tubular member 200 can comprise an arrangement of heat engines including: an outer heat engine 202 and an inner heat engine 204. The structure of the heat engines 202, 204 and their orientation within the heat pipe 120 work to transport heat from a region of high temperature to a region of low temperature. In one aspect, the tubular member 200, outer heat engine 202 and inner heat engine 204 can comprise copper or a copper alloy, wherein other metallic materials are considered. As depicted in FIG. 2, the heat pipe 120 can comprise a tubular member 200, wherein the tubular member can be oriented along the length of the tubular member. Regarding the heat engines, these engines can include a woven arrangement of wires to generate a conduit of water 220 and water vapor 222 to transfer heat 227 from the PCB 116 and SOC 118. In one aspect, the outer engine 202 can comprise a woven grouping of wire bundles 302 in a braided configuration as depicted in FIG. 3A. In an exemplary embodiment, a wire bundle 302 can comprise four wires per bundle, with the respective wires in the bundle comprising a 0.08 mm diameter. Formation of the braided configuration can also be defined by rate of bundle crossings in a given length dimension. For example, the wire bundles 304 can overlap 15 crossings per inch.

Further, the inner engine 204 can comprise another grouping of wire bundles 304 in a braided configuration as depicted in FIG. 3B. In a further aspect, the outer heat engine 202 is directly adjacent to the interior wall of the heating tube. The inner heat engine 204 is directly adjacent to the outer heat engine. The outer heat engine 202 can serve as the transport conduit for a transport liquid. In one aspect, the transport liquid can be water 220. The inner heat engine 204 can comprise an arrangement of wire bundles 304, wherein the wire bundles have a higher number of wires per bundle than the outer heat engine 202 and the interstitial spaces 226 between the overlapping wire bundles 304 of the inner heat engine and is smaller than the interstitial spaces between the overlapping bundles of the outer heat engine 202. For example, the wire bundles 304 can overlap each other 25 crossings per inch. Further, the outer heat engine 202 and inner heat engine 204 can be structurally adjusted or tuned via the physical parameters that define the overlapping weave (e.g., braiding) of the wires. These physical parameters can include the number of wires in a bundle, the diameter of wires, number of interstitial spaces 226 generated from the weave pattern, size of the interstitial spaces 226, and number of interstitial spaces per unit length. Adjusting these parameters that define the structural arrangement of the outer heat engine 202 and inner heat engine 204 results in adjustments of the fluid path during a heat-generation event caused by the computing device. For example, the fluid flow from the inner surface of the tubular member, through the outer engine, through the inner engine, into the vapor cavity and the fluid flow reversing through the same path is directly contingent of tuning/adjustments made to the physical parameters.

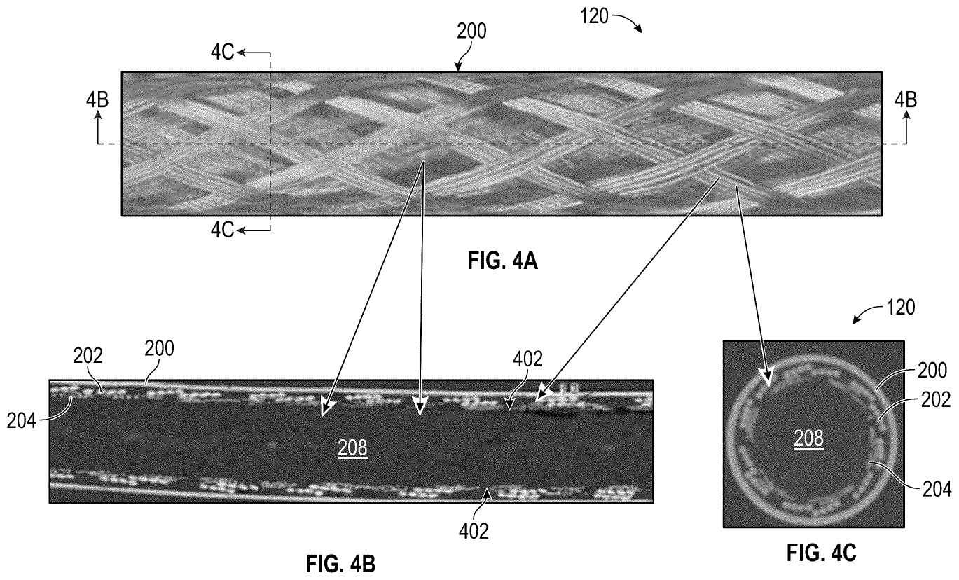

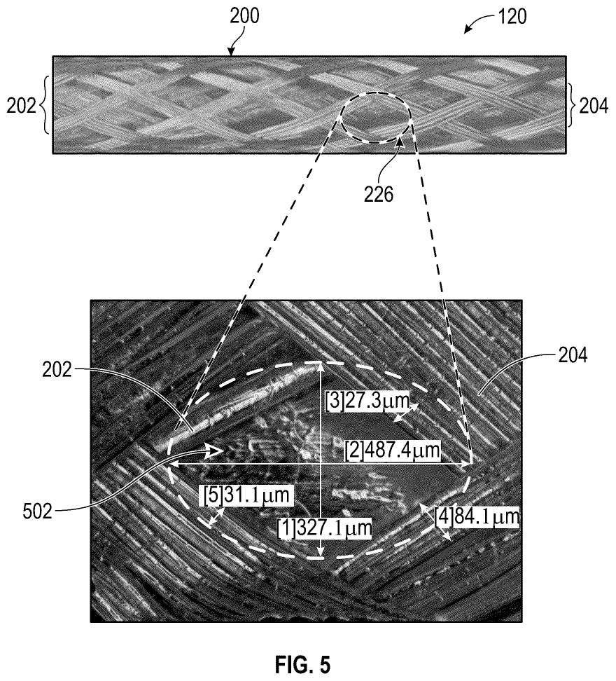

The inner heat engine 204 can be integrated into the outer heat engine 202, wherein both are inside the tubular member 200, as represented in FIG. 4B. The length view along the cutting line 4B and the end-wise view along cutting line 4C depict various views of the heating tube 120. As depicted in FIG. 4C, tubular member 200, the outer heat engine 202 and inner heat engine 204 can comprise a circular shell and can be oriented inside the tubular member 200. Further, the tubular member 200, outer heat engine 202, and inner heat engine 204 can be concentric to each other and circumscribe a vapor cavity 208. The orientation and the engagement of the two sets of weaved patterns of the outer heat engine and inner heat engine structurally define the fluid flow conduits for liquid transport fluid and vaporized transport fluid. The overlap of the weave patterns for the inner heat engine 204 and outer heat engine 202 can define interstitial spaces 226 that function as the fluid flow conduits. In a further aspect, the interstitial spaces 226 can define a pathway 402 that extends from the interior cavity 208 to the heating tube 120. As depicted in FIG. 5, an aperture of the interstitial space extending from the interior cavity to the inner wall of the tubular member 200 can be in the shape of a diamond or parallelogram, wherein other shapes are possible based on the overlapping structure created by the wire bundles 302, 304 associated with the inner heat engine and outer heat engine. For example, as depicted, the height of the aperture 502 of the interstitial space 226 can be approximately 327.1 micrometers and the width can be approximately 487.4 micrometers.

As depicted in FIG. 2, orienting the inner heat engine 204 inside of the outer heat engine 202 generates a supplemental cavity 236 for the transport fluid (e.g., water). In particular, the transport fluid can flow through the supplemental cavity 236 bounded by the inner surface of the tubular member 200 and the outer surface of the wires 206B of the inner heat engine 204. Accordingly, the transport fluid can flow over and around the larger wire 206A of the outer heat engine 202. During the heating event generated by the computing devices oriented in the temple member, the transport fluid will begin to heat up. Once the transport fluid reaches a boiling point, in the case of water 100° C., the transport fluid will change state into a vapor 222 and diffuse through the interstitial spaces 226 of the outer heat engine 202 through the inner heat engine 204 into the interior cavity 208. The heated vapor can rapidly transverse the length of the tubular member 200 via the conduit of the interior cavity 208. The interior cavity 208 is the cavity oriented at the center of the tubular member 200 that runs the length of the heating tube 120. Through heat transfer, the newly heated vapor can transfer heat along the length of the interior cavity 208. Along the length of the interior cavity 208, the vapor will eventually reach a region of the temple member 102 that the heating vapor will begin to condense. Further, while heated vapor traverses the length of the tube 120, a change in pressure is generated, resulting in a high-pressure region located at the distal end 124 of the heating tube 120. To achieve equilibrium, the higher-pressure region can force movement of the new condensate 230 of the previously vaporized transport liquid back through the interstitial spaces 226 of the outer heat engine 202 towards the proximal end of the heating tube 120 in proximity to the computing devices such as the PCB 116 and SOC 118. In an aspect, the heating tube 120 can be sealed at the proximal end and distal end. In a further aspect, the heating tube 120 can be pressurized.

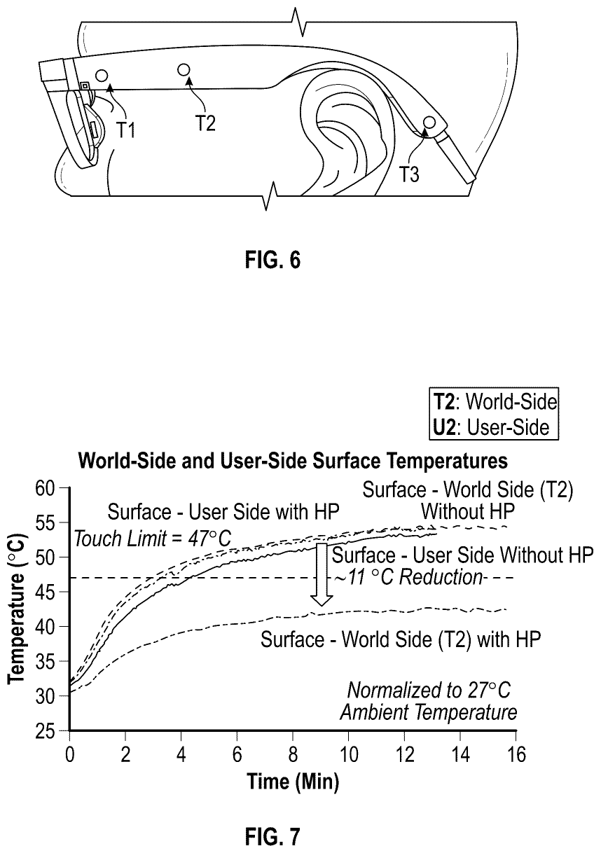

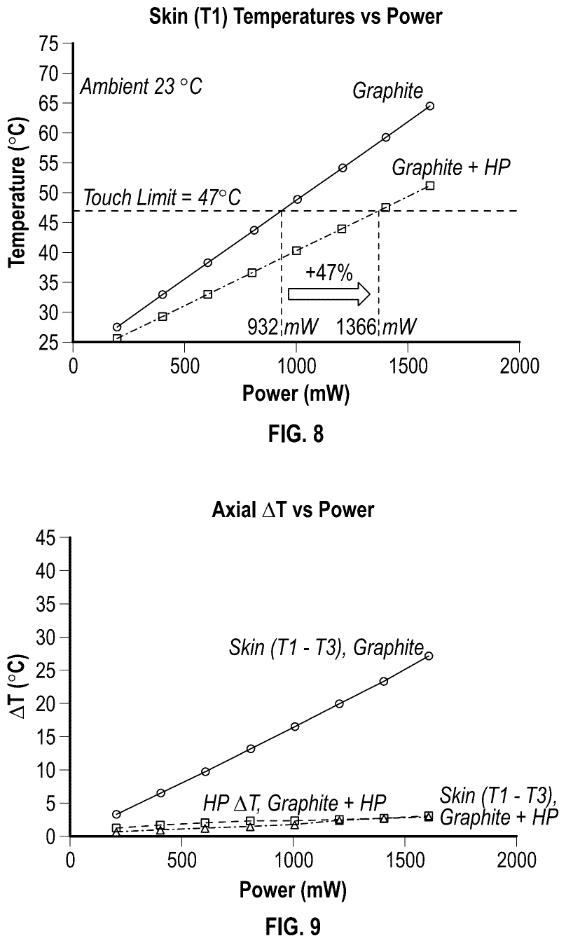

In determining the effectiveness of the disclosure, the testing verified the transfer of heat through points displaced along the length of the temple member 102; as depicted in FIG. 6, point T1 is located in the proximal region of the temple member 102 in proximity to the computing devices. Point T2 is located along the length dimension of the temple member 102 and point T3 is located towards the distal end. As depicted in FIG. 7, the integration of the heat pipe (HP) resulted in an 11 deg. Celsius drop in temperatures (approximately 51.8 deg. Fahrenheit) at point T2. Further, as depicted in FIG. 8, the implementation of a heating pipe 120 in the mixed reality device indicates a 47% improvement in comparison to a mixed reality device without the disclosed embodiment. The 47% improvement is poignant because more power can be output by the computing device which increases limits on the operating capacity. As further evidence, FIG. 9 depicts the impact on change in temperature with respect to the power applied. There is a positive correlation between applied power and temperature variation, such that an increase in power leads to an increase in temperature variation (ΔT). The applied power generates a steeper slope for a system relying on graphite alone (e.g., Skin (T1-T3), Graphite). In comparison to the disclosed system, the slope is far less steep for a system comprising graphite and the heat pipe of the disclosure (e.g., Skin (T1-T3), Graphite+HP) than graphite, which indicates a lower temperature variation when power is applied than when temperature is applied. A lower temperature variation exhibited by the disclosed system mitigates the negative impact of thermal cycling on system components. Further as shown in Table 1, a larger heat pipe (HP) can further reduce temperature variation.

TABLE 1
Impact of Heating Pipe Diameter on Temperature Variation

| Power | Lateral ΔT (° C.) | | |
|---|---|---|---|
| (mW) | Graphite | Graphite + 2 mm HP | Graphite + 1 mm HP |
| 600 | 7.3 | 3.11 | 5.5 |
| 1000 | 9.9 | 4.5 | 4.8 |
| 1600 | 16 | 9.1 | 11.1 |

As depicted in Table 1, the heating pipe with a larger diameter (2 mm) has less temperature variation than the smaller diameter (1 mm) heating pipe. Further, both variants of the heating pipe include a yield of less temperature variation that an embodiment with graphite alone (e.g., no heating pipe).

As described herein, a processor (e.g., a central processing unit (CPU) or microcontroller unit (MCU)) is an electronic component that is responsible for executing instructions and controlling the operation of an electronic device (e.g., a head-wearable device, a handheld intermediary processing device HIPD, or other computer system). There are various types of processors that may be used interchangeably or specifically required by embodiments described herein. For example, a processor may be (i) a general processor designed to perform a wide range of tasks, such as running software applications, managing operating systems, and performing arithmetic and logical operations; (ii) a microcontroller designed for specific tasks such as controlling electronic devices, sensors, and motors; (iii) a graphics processing unit (GPU) designed to accelerate the creation and rendering of images, videos, and animations (e.g., virtual-reality animations, such as three-dimensional modeling); (iv) a field-programmable gate array (FPGA) that can be programmed and reconfigured after manufacturing and/or customized to perform specific tasks, such as signal processing, cryptography, and machine learning; and (v) a digital signal processor (DSP) designed to perform mathematical operations on signals such as audio, video, and radio waves. One of skill in the art will understand that one or more processors of one or more electronic devices may be used in various embodiments described herein.

As described herein, controllers are electronic components that manage and coordinate the operation of other components within an electronic device (e.g., controlling inputs, processing data, and/or generating outputs). Examples of controllers can include (i) microcontrollers, including small, low-power controllers that are commonly used in embedded systems and Internet of Things (IoT) devices; (ii) programmable logic controllers (PLCs) that may be configured to be used in industrial automation systems to control and monitor manufacturing processes; and (iii) system-on-a-chip (SoC) controllers that integrate multiple components such as processors, memory, I/O interfaces, and other peripherals into a single chip; and/or DSPs. As described herein, a graphics module is a component or software module that is designed to handle graphical operations and/or processes, and can include a hardware module and/or a software module. The electronic components can also comprise electronic circuitry that can be oriented in the base. These electronic components can be configured to regulate charging of the controllers.

As described herein, memory refers to electronic components in a computer or electronic device that store data and instructions for the processor to access and manipulate. The devices described herein can include volatile and non-volatile memory. Examples of memory can include (i) random access memory (RAM), such as DRAM, SRAM, DDR RAM or other random access solid state memory devices, configured to store data and instructions temporarily; (ii) read-only memory (ROM) configured to store data and instructions permanently (e.g., one or more portions of system firmware and/or boot loaders); (iii) flash memory, magnetic disk storage devices, optical disk storage devices, other non-volatile solid state storage devices, which can be configured to store data in electronic devices (e.g., universal serial bus (USB) drives, memory cards, and/or solid-state drives (SSDs)); and (iv) cache memory configured to temporarily store frequently accessed data and instructions. Memory, as described herein, can include structured data (e.g., SQL databases, MongoDB databases, GraphQL data, or JSON data). Other examples of memory can include: (i) profile data, including user account data, user settings, and/or other user data stored by the user; (ii) sensor data detected and/or otherwise obtained by one or more sensors; (iii) media content data including stored image data, audio data, documents, and the like; and (iv) application data, which can include data collected and/or otherwise obtained and stored during use of an application; and/or any other types of data described herein.

As described herein, a power system of an electronic device is configured to convert incoming electrical power into a form that can be used to operate the device. A power system can include various components, including (i) a power source, which can be an alternating current (AC) adapter or a direct current (DC) adapter power supply; (ii) a charger input that can be configured to use a wired and/or wireless connection (which may be part of a peripheral interface, such as a USB, micro-USB interface, near-field magnetic coupling, magnetic inductive and magnetic resonance charging, and/or radio frequency (RF) charging); (iii) a power-management integrated circuit, configured to distribute power to various components of the device and ensure that the device operates within safe limits (e.g., regulating voltage, controlling current flow, and/or managing heat dissipation); and/or (iv) a battery configured to store power to provide usable power to components of one or more electronic devices.

As described herein, peripheral interfaces are electronic components (e.g., of electronic devices) that allow electronic devices to communicate with other devices or peripherals and can provide a means for input and output of data and signals. Examples of peripheral interfaces can include (i) USB and/or micro-USB interfaces configured for connecting devices to an electronic device; (ii) Bluetooth interfaces configured to allow devices to communicate with each other, including Bluetooth low energy (BLE); (iii) near-field communication (NFC) interfaces configured to be short-range wireless interfaces for operations such as access control; (iv) POGO pins, which may be small, spring-loaded pins configured to provide a charging interface; (v) wireless charging interfaces; (vi) global-position system (GPS) interfaces; (vii) Wi-Fi interfaces for providing a connection between a device and a wireless network; and (viii) sensor interfaces.

As described herein, sensors are electronic components (e.g., in and/or otherwise in electronic communication with electronic devices, such as wearable devices) configured to detect physical and environmental changes and generate electrical signals. Examples of sensors can include (i) imaging sensors for collecting imaging data (e.g., including one or more cameras disposed on a respective electronic device); (ii) biopotential-signal sensors; (iii) inertial measurement units (e.g., IMUs) for detecting, for example, angular rate, force, magnetic field, and/or changes in acceleration; (iv) heart rate sensors for measuring a user's heart rate; (v) SpO2 sensors for measuring blood oxygen saturation and/or other biometric data of a user; (vi) capacitive sensors for detecting changes in potential at a portion of a user's body (e.g., a sensor-skin interface) and/or the proximity of other devices or objects; and (vii) light sensors (e.g., ToF sensors, infrared light sensors, or visible light sensors) and/or sensors for sensing data from the user or the user's environment. As described herein, biopotential-signal-sensing components are devices used to measure electrical activity within the body (e.g., biopotential-signal sensors). Some types of biopotential-signal sensors include: (i) electroencephalography (EEG) sensors configured to measure electrical activity in the brain to diagnose neurological disorders; (ii) electrocardiogramhy (ECG or EKG) sensors configured to measure electrical activity of the heart to diagnose heart problems; (iii) electromyography (EMG) sensors configured to measure the electrical activity of muscles and diagnose neuromuscular disorders; and (iv) electrooculography (EOG) sensors configured to measure the electrical activity of eye muscles to detect eye movement and diagnose eye disorders.

As described herein, an application stored in a memory of an electronic device (e.g., software) includes instructions stored in the memory. Examples of such applications include (i) games; (ii) word processors; (iii) messaging applications; (iv) media-streaming applications; (v) financial applications; (vi) calendars; (vii) clocks; (viii) web browsers; (ix) social media applications; (x) camera applications; (xi) web-based applications; (xii) health applications; and (xiii) mixed reality (MR) applications, and/or any other applications that can be stored in memory. The applications can operate in conjunction with data and/or one or more components of a device or communicatively coupled devices to perform one or more operations and/or functions.

As described herein, communication interface modules can include hardware and/or software capable of data communications using any of a variety of custom or standard wireless protocols (e.g., IEEE 802.15.4, Wi-Fi, ZigBee, 6LoWPAN, Thread, Z-Wave, Bluetooth Smart, ISA100.11a, WirelessHART, or MiWi), custom or standard wired protocols (e.g., Ethernet or HomePlug), and/or any other suitable communication protocol, including communication protocols not yet developed as of the filing date of this document. A communication interface is a mechanism that enables different systems or devices to exchange information and data with each other, including hardware, software, or a combination of both hardware and software. For example, a communication interface can refer to a physical connector and/or port on a device that enables communication with other devices (e.g., USB, Ethernet, HDMI, or Bluetooth). In some embodiments, a communication interface can refer to a software layer that enables different software programs to communicate with each other (e.g., application programming interfaces (APIs) and protocols such as HTTP and TCP/IP).

Any data collection performed by the devices described herein and/or any devices configured to perform or cause the performance of the different embodiments described above in reference to any of the Figures, hereinafter the “devices,” is done with user consent and in a manner that is consistent with all applicable privacy laws. Users are given options to allow the devices to collect data, as well as the option to limit or deny collection of data by the devices. A user is able to opt-in or opt-out of any data collection at any time. Further, users are given the option to request the removal of any collected data.

It will be understood that, although the terms “first,” “second,” etc. may be used herein to describe various elements, these elements should not be limited by these terms. These terms are only used to distinguish one element from another.

The terminology used herein is for the purpose of describing particular embodiments only and is not intended to be limiting of the claims. As used in the description of the embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” can be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” can be construed to mean “upon determining” or “in response to determining” or “in accordance with a determination” or “upon detecting” or “in response to detecting” that the stated condition precedent is true, depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

What is claimed is:

1. A heating tube associated with a mixed reality device, comprising:
a tubular member comprising a proximal end and a distal end, wherein the tubular member comprises a shell and defines a vapor cavity and the tubular member is sealed at the proximal and distal ends;
an outer heating engine oriented in the vapor cavity, wherein the outer heating engine is adjacent to an inner surface wall of the tubular member; and
an inner heating engine oriented inside of the outer heating engine, wherein an outer surface of the inner heating engine defines a supplemental cavity bounded by an inner wall of the tubular member and the outer surface of the inner heating engine.

2. The heating tube of claim 1, wherein the outer heat engine comprises a plurality of wires, wherein the plurality of wires are grouped into bundles such that the bundles are oriented in an overlapping woven arrangement formed into an outer circular shell, and
the inner heat engine comprises a plurality of wires, wherein the plurality of wires are grouped into wire bundles such that the wire bundles are oriented in an overlapping woven arrangement formed into an inner circular shell.

3. The heating tube of claim 2, wherein a concentric orientation comprises the tubular member, the outer circular shell of the outer heating engine, and the inner circular shell of the inner heating engine, wherein the inner heating engine encapsulates the vapor cavity by an inner surface of the inner circular shell.

4. The heating tube of claim 2, wherein the wire bundles associated with the inner heat engine comprise more wires per bundle than the wire bundles associated with the outer heat engine.

5. The heating tube of claim 2, wherein a wire diameter of the plurality of wires associated with the outer heat engine are greater than a wire diameter of the plurality of wires associated with the inner heat engine.

6. The heating tube of claim 2, wherein the overlapping woven arrangement formed into the inner circular shell and the outer circular shell defines at least one interstitial space comprising an area dimension, wherein the area dimension of the at least one interstitial space associated with the outer heat engine is greater than the area dimension of the at least one interstitial space associated with the inner heat engine.

7. The heating tube of claim 1, further comprising a transport fluid, wherein the transportation fluid is encapsulated between an inner surface of the tubular member and an exterior surface of the outer heating engine.

8. The heating tube of claim 1, wherein the outer heating engine spans a length dimension between the proximal and the distal end of the tubular member.

9. The heating tube of claim 1, wherein the inner heating engine spans a length dimension between the proximal and the distal end of the tubular member.

10. The heating tube of claim 1, wherein the tubular member is composed of copper or copper alloy.

11. The heating tube of claim 1, wherein the tubular member is structured to be oriented in a temple cavity located in a temple member of a pair of glasses.

12. The heating tube of claim 1, wherein the tubular member is sealed at the proximal and distal end, and the tubular member is pressurized.

13. The heating tube of claim 1, wherein the tubular member comprises a diameter ranging from 1.0 mm to 2.0 mm.

14. A mixed reality device, comprising:
a computing device configured to be encapsulated by a structural component of the mixed reality device; and
a heating tube engaged adjacent to the computing device, comprising:
a tubular member comprising a proximal end and a distal end, wherein the tubular member comprises a shell and defines a vapor cavity and the tubular member is sealed at the proximal and distal ends;
an outer heating engine oriented in the vapor cavity, wherein the outer heating engine is adjacent to an inner surface wall of the tubular member;
an inner heating engine oriented inside of the outer heating engine, wherein an outer surface of the inner heating engine defines a supplemental cavity bounded by an inner wall of the tubular member and the outer surface of the inner heating engine; and
a transport fluid encapsulated by a boundary defined by an interior surface of the tubular member and an exterior surface of the outer heating engine.

15. The mixed reality device of claim 14, wherein the outer heat engine comprises a plurality of wires, wherein the plurality of wires are grouped into wire bundles such that the wire bundles are oriented in an overlapping woven arrangement formed into an outer circular shell, and
the inner heat engine comprises a plurality of wires, wherein the plurality of wires are grouped into wire bundles such that the wire bundles are oriented in an overlapping woven arrangement formed into an inner circular shell.

16. The mixed reality device of claim 15, wherein a concentric orientation comprises the tubular member, the outer circular shell of the outer heating engine, and the inner circular shell of the inner heating engine, wherein the inner heating engine encapsulates the vapor cavity by an inner surface of the inner circular shell.

17. The mixed reality device of claim 15, wherein the wire bundle associated with the inner heat engine comprises more wires per bundle than the wire bundle associated with the outer heat engine.

18. The mixed reality device of claim 15, wherein a wire diameter of the plurality of wires associated with the outer heat engine are greater than a wire diameter of the plurality of wires associated with the inner heat engine.

19. The mixed reality device of claim 15, wherein the overlapping woven arrangement formed into the inner circular shell and the outer circular shell defines at least one interstitial space comprising an area dimension, wherein the area dimension of the at least one interstitial space associated with the outer heat engine is greater than the area dimension of the at least one interstitial space associated with the inner heat engine.

20. The mixed reality device of claim 15, wherein the tubular member and the plurality of wires of the inner heat engine and outer heat engine are composed of copper or copper alloy.
